(19) United States
(12) Patent Application Publication
(10) Pub. No.: US 2024/0338504 A1
(43) Pub. Date: Oct. 10, 2024

(54) FLUID TURBINE SHROUD DESIGN METHOD

(71) Applicant: Vincent Loccisano, Wellesley, MA (US)

(72) Inventor: Vincent Loccisano, Wellesley, MA (US)

(21) Appl. No.: 18/629,574

(22) Filed: Apr. 8, 2024

Related U.S. Application Data
(60) Provisional application No. 63/495,091, filed on Apr. 8, 2023.

(51) Int. Cl. G06F 30/28; G06F 30/15

(52) U.S. Cl. CPC G06F 30/28; G06F 30/15

(57) ABSTRACT

In a method for designing the shroud and rotor of a shrouded fluid turbine, an example embodiment is a shrouded fluid-turbine system with a rotor coupled with an electrical generator, the rotor surrounded by at least one annular airfoil (shroud). A method for designing a shroud and rotor involves calculating 2D CFD of shroud-airfoil coordinates and calculating 3D CFD of shroud-airfoil and rotor models, as well as calculating 3D CFD actuator-disk shroud and rotor-model designs. The method also involves creating scaled shroud models along with modified rotor models for scale-model testing and for creating full-scale shroud and rotor models, and validating full-scale shroud and rotor designs.

### TECHNICAL FIELD

The present disclosure relates to shrouded fluid turbines and a method of designing shroud and rotor aerodynamic forms.

### BACKGROUND

A shrouded turbine or diffuser-augmented turbine is a fluid turbine with a rotor that is surrounded by an annular duct, shroud, diffuser, or cowling. Ringed airfoils/shrouds are known to improve mass flow through a rotor. By diffusing and expanding a wake, a shroud increases wake-area size, reducing its pressure. This enables increased mass flow and greater power extraction at the rotor. A drawback of shrouds is their added weight. Turbine shrouds are commonly constructed of rigid, fiber-reinforced polymers, making them heavy, requiring substantial tower structures to support their weight. A side gust impacts them like a bluff body. This force strains the turbine's tower and other structural components. The problem increases with large rotor-swept areas requiring large shrouds. To withstand forces like side gusts, shrouds may be constructed of relatively light, flexible materials.

### SUMMARY

The present disclosure generally relates to a method of design of the aerodynamic components of a shroud on a shrouded fluid turbine. In an example embodiment, a shrouded fluid turbine system has a rotor that is surrounded by an annular airfoil or shroud.

A shrouded fluid turbine shroud-design method includes, in combination, 2D Computer Fluid Design (CFD), 3D CFD, Finite-Element Analysis (FEA), scale-model testing and validation, and full-scale testing and validation. Validation gauges the quality of each stage of development while providing information for improving the process.

The method applies to a fluid-turbine system disclosed. The fluid turbine has a rotor assembly; an annular duct with annular leading edge; an annular trailing edge; an inner surface extending between the leading edge and the trailing edge; and an outer surface extending between the leading edge and the trailing edge, arranged on a common central axis. The inner surface of the annular duct is in fluid communication with the rotor assembly.

The fluid turbine may also include another annular duct having a leading edge; a trailing edge; an inner surface extending between the leading edge and the trailing edge; and an outer surface extending between the leading edge and the trailing edge, arranged on a common central axis. The inner surface of this annular duct is in fluid communication with the outer surface of the other annular duct. In both annular ducts, the airfoil cross section is oriented such that the inner surface is a lift surface and the outer surface is a pressure surface.

In an aspect of the embodiment, a design-support program has an initial stage for designing an annular duct involving two-dimensional computer fluid design (2D-CFD) to develop two-dimensional geometry for an axis-symmetric shroud design. 2D CFD involves scaling airfoil cross-section geometry and varying relative placement and angle of attack of airfoil geometry. Following the scaling process, chord lengths and surface thicknesses are recorded. Another embodiment of the initial stage of the method for designing an annular duct involves a data spreadsheet consisting of shroud geometry coordinates. The data spreadsheet is employed to parameterize driving dimensions including flow area, flow angles of attack, shroud-airfoil chord lengths and shroud-airfoil thicknesses. Further, airfoil contours may be varied along with the parameters to assess the effect on performance and drag. The result is an axis-symmetric form called “shroud definition.”

In another aspect of the embodiment, a design-support program involves developing a computer-modeled mesh form based on the shroud definition in preparation for a CFD study. Power extraction at the rotor plane is simulated by an actuator disk boundary condition applied to the CFD model. Various pressure-drop profiles may be created for the actuator disk boundary condition, representing various levels of power extraction. Results from this initial CFD study provide initial estimates of power generation from the designed system. Although the system measurements are based on an axial fluid-stream flow direction, (or “zero-degree yaw”), and while assuming zero drag on system components, these assumptions are made for all designs tested so that a candidate design may be chosen appropriately. In this manner, multiple shroud designs may be tested and evaluated. Results of the CFD analysis parameters may be tabulated in a spreadsheet and compared in order to study the effects of parameter changes.

In another aspect of the embodiment, a design-support program uses three-dimensional computer fluid design (3D-CFD). A 3D CFD model provides a better understanding of the effects of non-symmetric geometry. For example, a faceted annular airfoil produces different results than a round annular airfoil. Support structures such as tower and struts also affect the aerodynamic performance; 3D CFD will show these differences in the results. A pressure-drop actuator disk represents rotor power extraction and provides measured pressure drop at the rotor plane, referred to as cT, and measured velocity of the axial fluid-stream at the rotor plane, referred to as uR. The results provide insight into the separation of flow from aerodynamic surfaces and wake characteristics caused by non-symmetric annular duct features. Other non-symmetric annular duct features include off-axis yaw, flap deployment or faired rotor blades.

In yet another aspect of the embodiment, a design-support program uses validation tests that involve the production of a scale model of the turbine shrouds for use in a wind tunnel. Wind-tunnel tests typically exhibit low Reynolds numbers and so it is practical to create rotors designed specifically for a wind-tunnel environment. The design-support program also includes full-scale tests of rotor blade designs.

In yet another aspect of the embodiment, a design-support program uses full-scale prototype testing and correlation with 2D and 3D CFD results to validate the design process and make necessary adjustments to improve the process.

### BRIEF DESCRIPTION OF THE DRAWINGS

FIG. 1 is a schematic of an example embodiment depicting a method for designing a shrouded fluid turbine system;

FIG. 2 is a front-perspective view of an example turbine of the embodiment;

FIG. 3 is a rear-perspective view of an iteration of an example turbine of the embodiment;

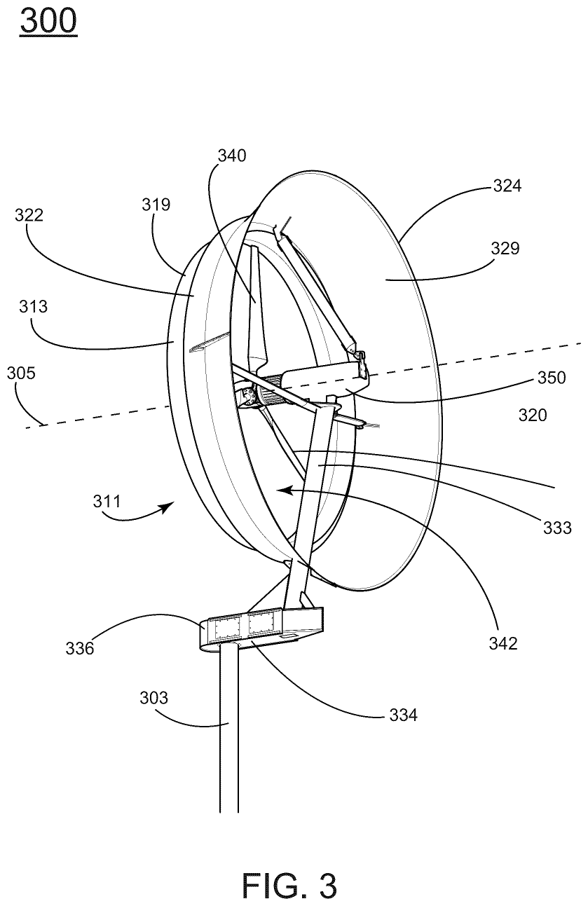

FIG. 4 is a perspective view of a turbine shroud and ejector shroud segments;

FIG. 5 is a spreadsheet depicting 2D CFD parameters and results;

FIG. 6 is a perspective view of a turbine shroud and ejector shroud segments depicting significant shroud-flow areas, and related spreadsheet data;

FIG. 7 depicts a 3D CFD actuator disk velocity plot;

FIG. 8 depicts a 3D CFD shroud model velocity plot with the turbine yawed off axis;

FIG. 9 is a perspective view of a scaled turbine shroud test model.

### DETAILED DESCRIPTION

A design method for aerodynamic forms related to ducted or shrouded fluid turbines. A shroud- and rotor-design method for developing a coupled aerodynamic system. A method for designing annular airfoils includes two-dimensional computer fluid dynamics (2D CFD) and multiple stages of three-dimensional computer fluid dynamics (3D CFD) to evaluate candidate airfoil designs. In tandem, a method for designing a rotor that is intended to be coupled to the aforementioned shroud design employs an actuator disk to evaluate rotor-plane coefficient of pressure, Cp and rotor-plane fluid velocity, UR. Final evaluation is achieved in scale-model wind-tunnel testing and full-scale design testing. Results from test models and full-scale final designs validate initial 2D CFD and 3D CFD processes.

The term “rotor” or “rotor assembly” refers to any assembly in which blades are attached to a shaft and able to rotate, allowing for the generation of power or energy from fluid rotating the blades. Example embodiments depict a fixed-blade rotor or a rotor assembly having blades that do not change configuration so as to alter their angle of attack, or pitch. Any type of rotor assembly may be used with the fluid turbine systems (e.g., shrouded fluid turbine systems) of the present disclosure, for example a variable-pitch-blade rotor, a propeller-like rotor, or a rotor or stator assembly.

As used herein, “duct” or “shroud” refers to an airfoil ring having a circular cross section, an oval cross section, or a polygonal cross section, and can be have a continuous inner and outer surface free of gaps, or inner and outer surface portions interspaced with gaps, slots or holes.

In certain embodiments, the leading edge of a turbine-shroud assembly may be considered the front of the fluid turbine system, and the trailing edge of a turbine-shroud assembly or of an ejector shroud assembly may be considered the rear. A first component of the fluid turbine system proximal to the front of the turbine system may be considered “upstream” of a second, “downstream” component, proximal to the rear of the turbine system.

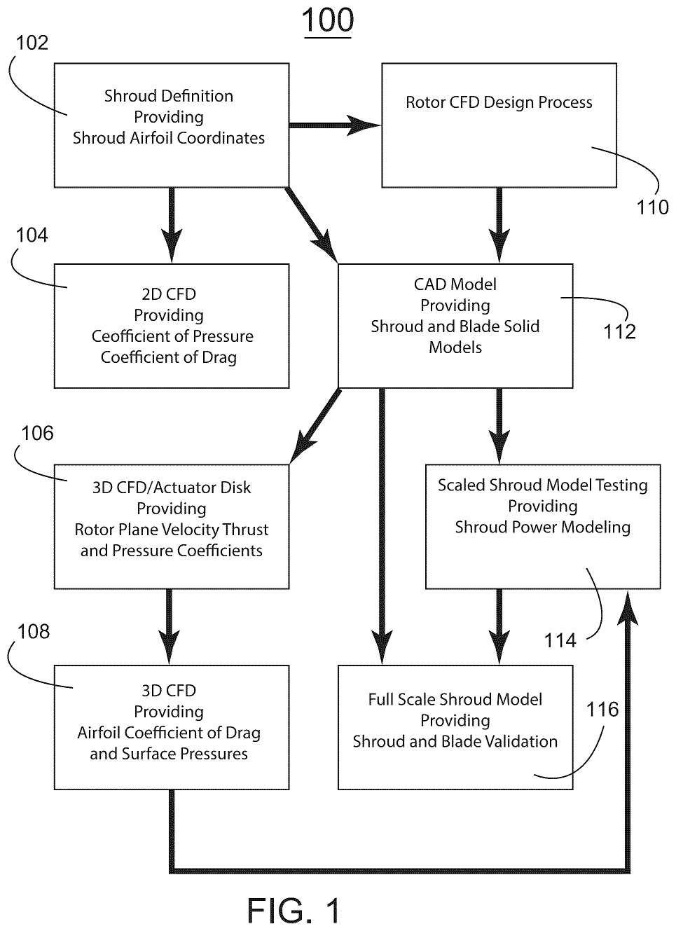

FIG. 1 shows a diagram of the method's steps. A first step 102 includes initial airfoil definition by defining airfoil coordinates. A next step 104 includes two-dimensional computer fluid dynamics (2D CFD), allowing multiple iterations to be evaluated rapidly, and candidate designs chosen without excessive experimentation and trial.

In tandem with the initial design of the shroud airfoils, a step 110 includes initial rotor design CFD and a step 112 includes the computer-aided design (CAD) modeling of the initial rotor design and initial shroud airfoils, providing rotor blade and shroud airfoil 3D solid models.

A following step 106 includes further evaluation of chosen candidate designs, in increasing detail, employing 3D CFD, including a rotor-plane actuator disk to provide estimated rotor plane velocity; UR, rotor-plane thrust coefficient CT and rotor-plane pressure coefficient Cp. This step includes information related to the shroud CFD as well as the rotor CFD.

A following step 108 includes further evaluation of chosen candidate shroud designs, in greater detail, by employing three-dimensional computer fluid dynamics (3D CFD) to determine the shroud exit-plane coefficient of pressure (Cp) as well as shroud geometry coefficient of drag (CD) and surface pressures.

A following step 114 includes a scale model of rotor and shrouds. High Reynolds numbers require modified rotor blades for scale model testing in a wind tunnel. Modified rotor design combined with a scaled shroud model, used in wind tunnel testing, provides estimated turbine power output.

A final step 116 involves full-scale testing of the shroud-and-rotor combination in a field-tested turbine. Shroud and blade validation informs the accuracy of earlier steps, which may then be adjusted for improved outcomes from the design method.

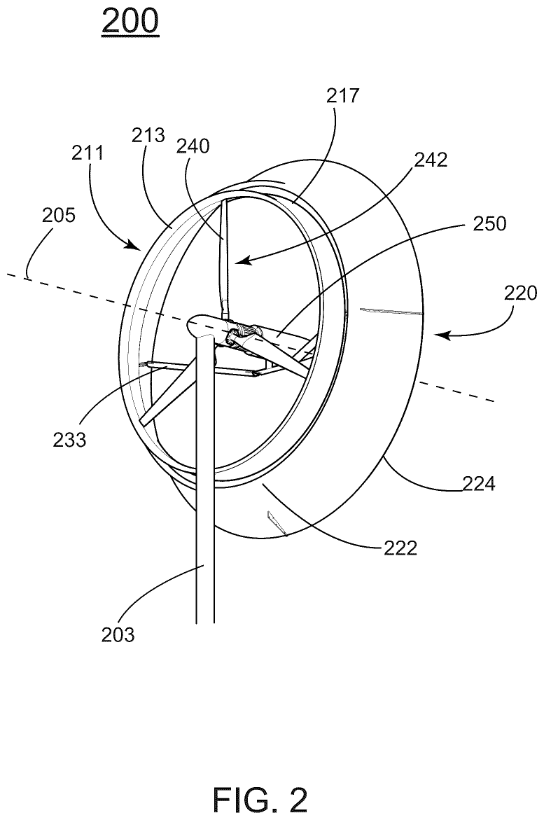

To this end, the embodiment is a method of designing a ducted fluid turbine as shown in FIG. 2. The method of design is for an example fluid turbine 200 comprising, as taught herein, a ducted or shrouded fluid turbine that includes an annular airfoil 211 (also referred to as a turbine shroud), which is in fluid communication with the circumference of a rotor plane 242. The turbine shroud comprises a leading edge 213 and a trailing edge 217 and is supported by struts 233. Struts 233 are engaged at the proximal end with the nacelle 250 and at the distal end with the leading edge 213 of the turbine shroud 211. The turbine shroud 211, rotor 240 and nacelle 250 are coaxial about a central axis 205. The structure of the system, as described herein, also allows a shroud structure with a turbine shroud 211 and an ejector shroud 220. The ejector shroud 220 is in fluid communication with the exit plane 217 of the turbine shroud 211. The ejector shroud 220 comprises a leading edge 222 and a trailing edge 224 and is supported by shroud struts 206 that are engaged at the proximal end with the leading edge 213 of the turbine shroud 211 and are engaged at the distal end with the leading edge 222 of the ejector shroud 220. The fluid turbine is supported by a tower structure 203.

Some embodiments include annular airfoils with faceted segments. The method of design is employed to design such faceted segments in an example fluid turbine 300 comprising a ducted or shrouded fluid turbine with an annular airfoil 311 (referred to as a turbine shroud), which is in fluid communication with the circumference of a rotor plane 342. The turbine shroud comprises a leading edge 313 and a trailing edge 317 and is supported by struts 333. Struts 333 are engaged at the proximal end with the nacelle 350 and at the distal end with the turbine shroud 311. The turbine shroud 311, rotor 340 and nacelle 350 are coaxial about a central axis 305. The structure of the system also allows a shroud structure that has turbine shroud 311 and an ejector shroud 320. The ejector shroud 320 is in fluid communication with the exit plane 317 of the turbine shroud 311. The ejector shroud 320 comprises a leading edge 322 and a trailing edge 324, and is supported by shroud struts 306 that are engaged at the proximal end with the turbine shroud 311 and are engaged at the distal end with the leading edge 322 of the ejector shroud 320. The fluid turbine is supported by a tower structure 303.

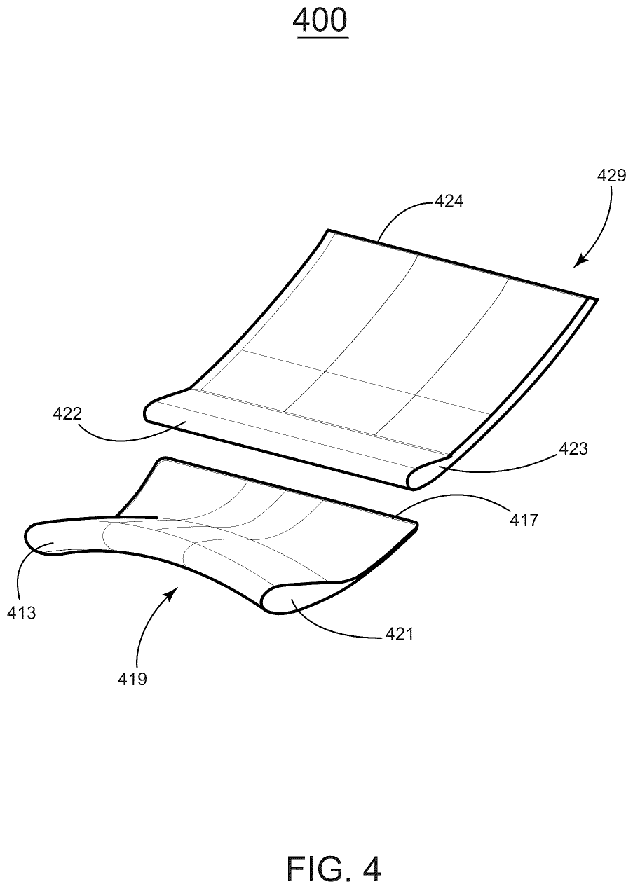

FIG. 4 shows a turbine shroud segment 419 and ejector shroud segment 429. The turbine shroud segment 419 comprises a leading edge 413 and a trailing edge 417 and an airfoil (profiled in cross section 421). The ejector shroud segment 429 comprises a leading edge 422, a trailing edge 424 and an airfoil (profiled in cross section 423). The method described herein is applied in the first step 102 (FIG. 1) to shroud-airfoil profiles, including turbine-shroud airfoil profile 421 (FIG. 4) and ejector-shroud airfoil profile 423. Two-dimensional airfoil profiles 421, 423 are used in 2D CFD as previously described and are further employed to generate the 3D geometry that makes up turbine shroud segment 419 and ejector shroud segment 429.

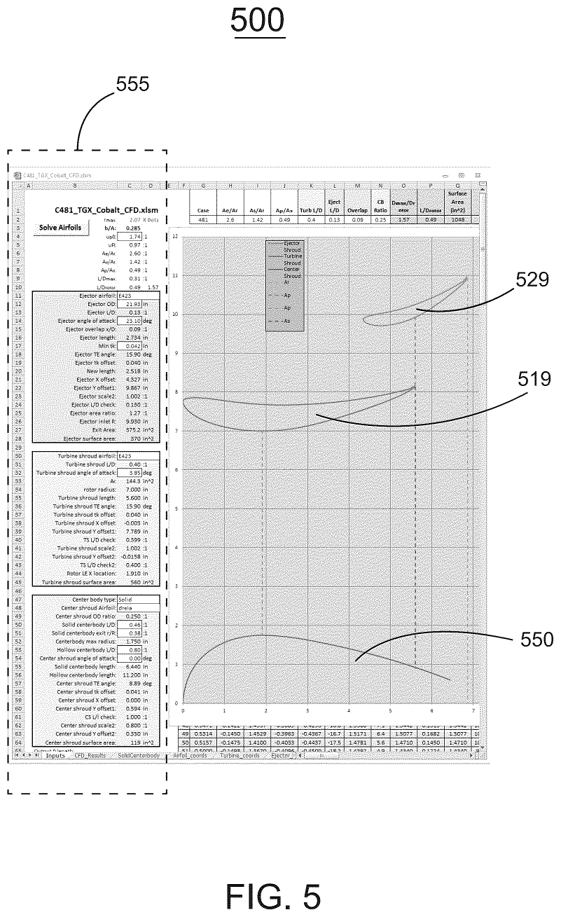

FIG. 5 depicts results from 2D CFD, showing a diagram of a nacelle 550, a turbine shroud 519 and an ejector shroud 529. Characteristics of shroud geometry are displayed in the table in the dashed boundary 555. Important results from the 2D CFD include coefficient of pressure (Cp) and shroud geometry coefficient of drag (CD).

As understood by one skilled in the art, the aerodynamic principles presented in this disclosure are not restricted to a specific fluid, and may apply to any fluid, including air. The aerodynamic principles of a VDWT system in air apply to hydrodynamic principles in a VDWT system designed for water.

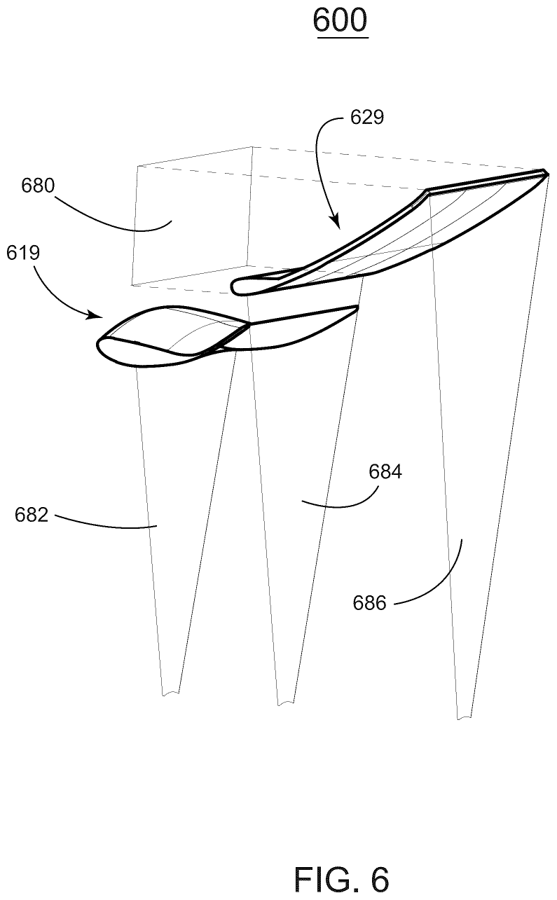

FIG. 6 shows flow areas that are important to the shroud design. The ejector-diffusion area 680 relates to the frontal area of the ejector shroud 629. The rotor area 682 denotes the rotor plane as it relates to the turbine-shroud segment 619. Other important flow areas include the turbine shroud 619 exit area 684 and ejector-shroud 629 exit area 686.

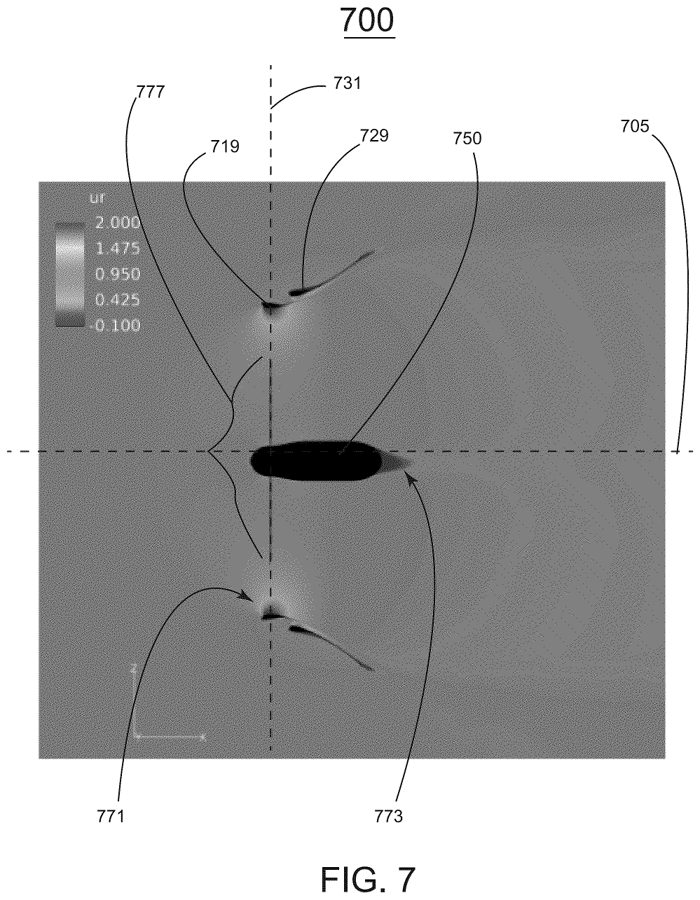

After screening different shroud designs with 2D CFD in previous steps, a more detailed 3D CFD model based on the 3D CAD model is developed to better understand effects of non-symmetric geometry, such as a faceted ejector, struts, or tower effects. FIG. 7 shows an example velocity plot from a 3D actuator disk CFD model, including turbine-shroud segments 719, ejector-shroud segments 729 and a nacelle 750; shroud segments are symmetrical about the central axis 705. A pressure-drop actuator disk 777 is placed on the rotor plane 731, between the nacelle 750 and the turbine-shroud segments 719. Changes in color show variations in fluid-stream velocity, the highest velocity shown in red 771 and the lowest velocity shown in blue 773, indicating separation from the body. The pressure drop actuator disk 777 is used to represent the rotor power extraction and provide power, CT (measured pressure drop at rotor plane) and UR (velocity at rotor plane) estimates. Study of the post-processing results of the 3D model can give insight to the separation and wakes caused by the periodic and non-symmetric shroud features.

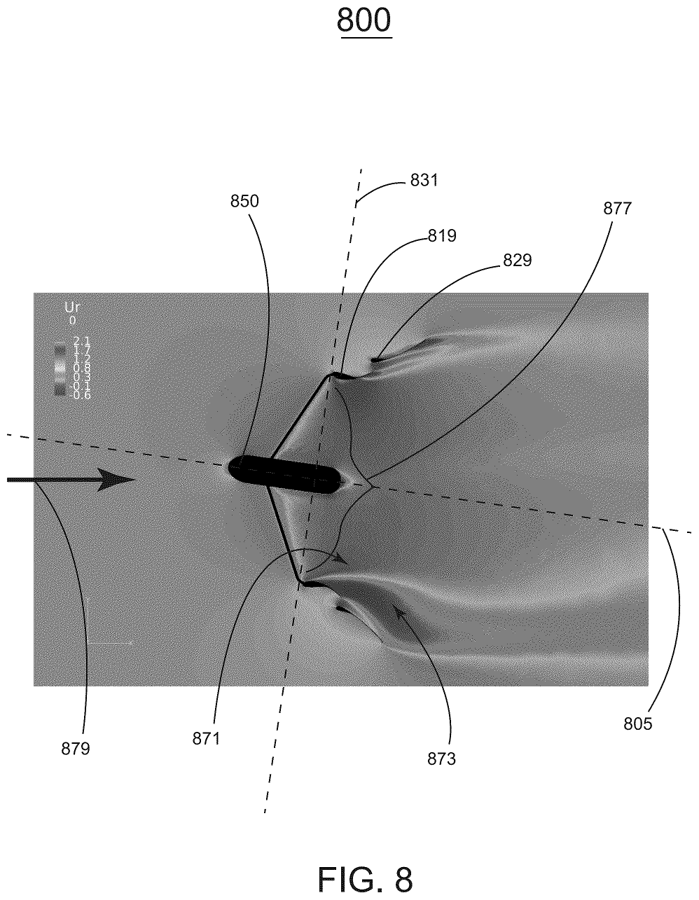

FIG. 8 shows an example of the CAD model used for the 3D CFD run to predict drag at a yaw angle with the ejector shroud segments 829 deployed at different angles. The turbine shroud 819, ejector shroud 829 and nacelle 850 remain symmetrical about the central axis 805, and the rotor plane 831 remains perpendicular to the central axis 805 and the actuator disk 877, while these components are rotated with respect to the fluid stream flow 879. Red areas 871 represent areas of highest fluid-stream velocity and blue areas 873 represent areas of lowest fluid-stream velocity. To understand the drag of a shroud design at different yaw angles, the shroud geometry is run at different angles to the wind in CFD. In other words, the central axis 805 is at an angle with the fluid stream flow direction 879. In many cases the same mesh model from the 3D actuator-disk run (FIG. 7) can be used, but with the actuator disk C set to 0 to represent the extreme wind cases where the rotor is faired out of the wind and not producing power.

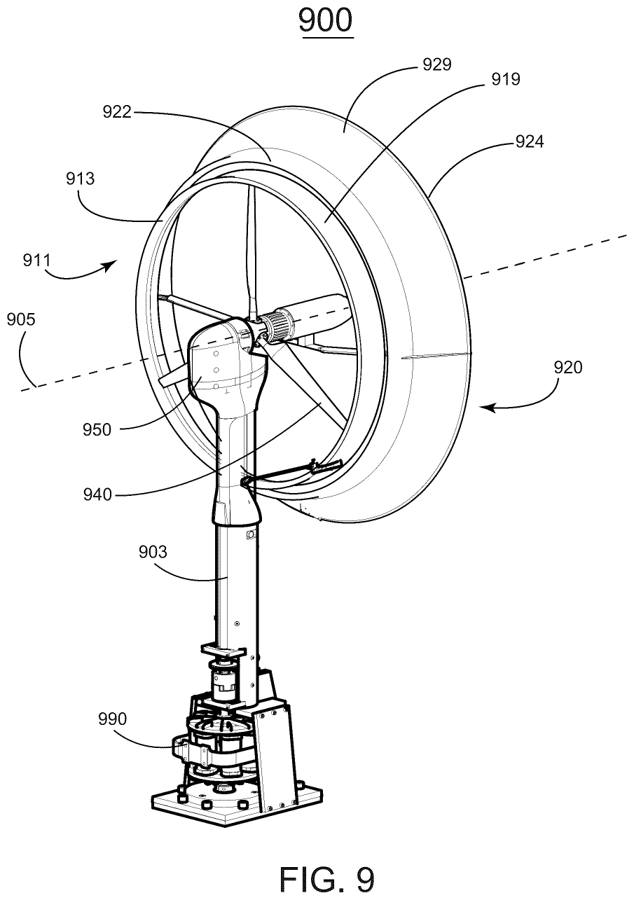

FIG. 9 shows a scale model 900 of a turbine design with a modified rotor and a dynamometer. Wind-tunnel testing of a shroud configuration is used to validate the CFD results and predict full-scale performance. A scaled-down test model with a rotor diameter greater than 24″ is built to be tested in a subsonic wind tunnel with rotor power measured by a torque meter, and loading provided by either a water-current dynamometer or an eddy-current dynamometer.

The scale model 900 comprises a ducted or shrouded fluid turbine scale model that includes at least one annular airfoil 911 (referred to as a turbine shroud) which is in fluid communication with the circumference of a rotor plane 942. The turbine shroud comprises a series of shroud segments 919, each including a leading edge 913 and a trailing edge 917, and is supported by struts 933. Struts 933 are engaged at the proximal end with the nacelle 950 and at the distal end with the turbine shroud 911. The turbine shroud 911, rotor 940 and nacelle 950 are coaxial about a central axis 905. The structure of the system, as described herein, also allows a shroud structure including a turbine shroud 911 and an ejector shroud 920. The ejector shroud 920 comprises ejector segments 929 and is in fluid communication with the exit plane 917 of the turbine shroud 911. The ejector shroud segments 929 each comprise a leading edge 922 and a trailing edge 924 and are supported by shroud struts 906 that are engaged at the proximal end with the turbine shroud 911 and at the distal end with the leading edge 922 of the ejector shroud 920. The fluid turbine is supported by a tower structure 903. A dynamometer 990 is mechanically engaged through the tower 903 with the rotor 940. One skilled in the art understands that engagement between the dynamometer 990 and the rotor 940 may be accomplished by a shaft with a right angle gear inside the nacelle 950, or may be accomplished with various belts and pulleys or other shaft and gear combinations.

1. A method for designing fluid turbine, the method comprising:
providing an annular airfoil surrounding a rotor assembly; and
defining airfoil coordinates for said annular airfoil; and
deriving coefficient of pressure and coefficient of drag from 2D CFD results of said airfoil coordinates; and
defining an annular airfoil coefficient of drag and annular airfoil surface pressures from 3D CFD results; and
designing a 3D CAD model of said annular airfoil coupled with a rotor assembly according to said 2D and 3D CFD results.

2. The method of claim 1 further comprising:
including a 3D CFD actuator disk to define and evaluate rotor plane fluid velocity and rotor plane coefficient of pressure.

3. The method of claim 2 further comprising:
designing a 3D CAD model of a rotor blade of said rotor assembly according to said rotor plane fluid velocity and rotor plane coefficient of pressure.

4. The method of claim 1, 2 or 3 further comprising:
producing a scale model of said fluid turbine for wind tunnel testing.

5. The method of claim 1, 2 or 3 further comprising:
producing a full scale model of said fluid turbine.

6. A method for designing a combination annular-airfoil and a rotor, in a fluid turbine system including a rotor having at least one rotor blade providing a rotor swept-area that is arranged about a central axis, an annular airfoil coaxial with said rotor and surrounding said rotor swept-area, said method comprising:
providing annular-airfoil coordinates that define airfoil cross-sectional area and location of airfoil cross-section with respect to said rotor; and
calculating two-dimensional computer fluid dynamics of said annular-airfoil, determining annular-airfoil coefficient of pressure and coefficient of drag; and
providing a rotor design and an annular-airfoil design in a three-dimensional computer-aided-design model; and
providing an actuator disk denoting coefficient of velocity, coefficient of thrust and coefficient of pressure of said rotor design in said rotor swept-area; and
calculating three-dimensional computer fluid dynamics of said annular-airfoil three-dimensional computer-aided-design and said actuator disk determining coefficient of drag and annular-airfoil surface pressures; and
providing a scaled test-model including a scaled model of said annular-airfoil and a scaled model of said rotor that is modified to account for Reynolds numbers realized in a wind tunnel; and
testing said scaled test-model in said wind tunnel to determine power output predicted of said annular-airfoil and said rotor in combination; and
providing a full scale model of said annular-airfoil and said rotor, further providing an electrical generator rotationally engaged with said rotor for producing electrical energy; and
validating electrical energy produced by said full scale model, and comparing electrical energy produced with said power output predicted; and
modifying said two-dimensional and said three-dimensional computer fluid dynamics to account for discrepancies between said power output predicted and said electrical energy produced.

7. A method for designing a combination first annular-airfoil and a second annular-airfoil and a rotor, in a fluid turbine system including a rotor having at least one rotor blade providing a rotor swept-area that is arranged about a central axis, said first annular-airfoil having a leading edge and a trailing edge and being coaxial with said rotor and surrounding said rotor swept-area, said second annular-airfoil having a leading edge and a trailing edge and surrounding said trailing edge of said first annular-airfoil, said method comprising:
providing annular airfoil coordinates that define first annular-airfoil cross-sectional area and second annular-airfoil cross sectional area and location of airfoil cross-sectional areas with respect to each other and with respect to said rotor; and
calculating two-dimensional computer fluid dynamics of said first and second annular-airfoils, determining coefficient of pressure and coefficient of drag of combination of first annular-airfoil and second annular-airfoil; and
providing a rotor design and an annular-airfoil design in a three-dimensional computer-aided-design model; and
providing an actuator disk denoting coefficient of velocity, coefficient of thrust and coefficient of pressure of said rotor design in said rotor swept-area; and
calculating three-dimensional computer fluid dynamics of said annular-airfoil three-dimensional computer-aided-design and said actuator disk determining coefficient of drag and combination first and second annular-airfoil surface pressures; and
providing a scaled test-model including a scaled model of said first and second annular-airfoil and a scaled model of said rotor that is modified to account for Reynolds numbers achieved in a wind tunnel; and
testing said scaled test-model in a wind tunnel to determine power output predicted of said first and second annular-airfoil and said rotor in combination; and
providing a full scale model of said first and second annular-airfoil and said rotor, further providing an electrical generator rotationally engaged with said rotor for producing electrical energy; and
validating electrical energy produced by said full scale model, and comparing electrical energy produced with said power output predicted; and
modifying said two-dimensional and said three-dimensional computer fluid dynamics to account for discrepancies between said power output predicted and said electrical energy produced.
